(19) United States
(12) Patent Application Publication
(10) Pub. No.: US 2023/0225175 A1
(43) Pub. Date: Jul. 13, 2023

(54) DISPLAY PANEL

(71) Applicant: Samsung Display Co., Ltd., Yongin-si (KR)

(72) Inventors: JEONGHO LEE, Asan-si (KR); SWAE-HYUN KIM, Asan-si (KR); YOUHAN MOON, Bucheon-si (KR)

(21) Appl. No.: 18/093,729

(22) Filed: Jan. 5, 2023

(30) Foreign Application Priority Data
Jan. 10, 2022 (KR) 10-2022-0003650

(51) Int. Cl. H10K 59/80; H10K 59/121; H10K 59/131

(52) U.S. Cl. CPC H10K 59/873; H10K 59/1213; H10K 59/131

(57) ABSTRACT

A display panel includes: a signal line extending in a first direction; an organic insulating film overlapping a first part of the signal line and not overlapping a second part of the signal line; a pixel electrically connected to the signal line and including a transistor and a light emitting element including a pixel electrode on the organic insulating film; and a conductive pattern covering at least a portion of an edge of the second part of the signal line.

### CROSS-REFERENCE TO RELATED APPLICATIONS

The present application claims priority to and the benefit of Korean Patent Application No. 10-2022-0003650, filed on Jan. 10, 2022, the entire content of which is hereby incorporated by reference.

### BACKGROUND

### 1. Field

Aspects of some embodiments of the present disclosure relate to a display panel.

### 2. Description of the Related Art

A display device for displaying images to users, such as a television, a mobile phone, a tablet, a computer, a navigation system, a game machine, and the like may include a display panel for generating and displaying the image. The display panel may include a plurality of pixels, a driver that drives the pixels, and signal lines that transmit electrical signals to the pixels.

Moreover, the pixels, the driver and the signal lines may be damaged or defective by moisture or particles introduced from the outside, and in order to prevent or reduce this, it may be desirable to study the structure of the display panel or the manufacturing process of the display panel.

The above information disclosed in this Background section is only for enhancement of understanding of the background and therefore the information discussed in this Background section does not necessarily constitute prior art.

### SUMMARY

Aspects of some embodiments of the present disclosure relate to a display panel, and for example, to a display panel with improved reliability.

Aspects of some embodiments of the present disclosure include a signal line and a display panel with relatively improved reliability by forming a conductive pattern that blocks moisture inflow to the signal line exposed from the organic insulating film with a simplified process and that prevent or reduce damage to the inorganic layer formed on the signal line at the same time.

Aspects of some embodiments of the inventive concept include a display panel including: a signal line extending in a first direction; an organic insulating film overlapping a first part of the signal line and not overlapping a second part of the signal line; a pixel electrically connected to the signal line and including a transistor and a light emitting element including a pixel electrode on the organic insulating film; and a conductive pattern covering at least a portion of an edge of the second part of the signal line.

According to some embodiments, a width of the conductive pattern in a second direction intersecting the first direction may be greater than a width of the second part in the second direction.

According to some embodiments, one end of the conductive pattern may include a plurality of protruding parts arranged in the first direction.

According to some embodiments, the conductive pattern may include a material different from that of the signal line.

According to some embodiments, the conductive pattern may include the same material as the pixel electrode.

According to some embodiments, the signal line may include a plurality of conductive layers that sequentially stacked, wherein the conductive pattern may cover each of side surfaces of the plurality of conductive layers.

According to some embodiments, the display panel may further include at least one dam extending in the second direction intersecting the first direction and overlapping the second part of the signal line, wherein the at least one dam may be spaced apart from the organic insulating film.

According to some embodiments, the at least one dam may include: a first sub-dam on the second part of the signal line; and a second sub-dam on the first sub-dam, wherein at least one of the first sub-dam or the second sub-dam may include the same material as the organic insulating film.

According to some embodiments, a portion of the conductive pattern may be between the first sub-dam and the second sub-dam.

According to some embodiments, the at least one dam may be on the conductive pattern.

According to some embodiments, the dam may be provided in plurality, and the plurality of dams may be spaced apart from each other in the first direction.

According to some embodiments, the display panel may further include an encapsulation layer on the light emitting element, and including a plurality of inorganic layers and at least one organic layer between the plurality of inorganic layers, wherein at least one of the plurality of dams may be spaced apart from the organic layer.

According to some embodiments, the plurality of inorganic layers may cover the conductive pattern.

According to some embodiments, the signal line may include a data line providing a data voltage to the pixel and a power line providing a power supply voltage to the pixel.

According to some embodiments of the inventive concept, a display panel includes: a substrate including a display area and a non-display area; a pixel on the display area and including a light emitting element; a signal line electrically connected to the pixel and extending in one direction from the display area to the non-display area; an organic insulating film on the signal line and exposing a portion of the signal line; a conductive pattern on the non-display area and covering the portion of the signal line; and at least one dam overlapping the conductive pattern and crossing the signal line.

According to some embodiments, the light emitting element may include: a pixel electrode on the organic insulating film; a counter electrode on the pixel electrode; and a light emitting layer between the pixel electrode and the counter electrode, wherein the conductive pattern may be spaced apart from the pixel electrode.

According to some embodiments, the conductive pattern may include the same material as the pixel electrode.

According to some embodiments, the signal line may include a material different from that of conductive pattern.

According to some embodiments, an edge of the portion of the signal line may be in contact with the conductive pattern.

According to some embodiments, the signal line may include: data lines extending in a first direction, arranged in a second direction intersecting the first direction, and applying a data voltage to the pixel; and at least one power line extending in the first direction and applying a power supply voltage to the pixel.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of a display device according to some embodiments;

FIG. 2 is an exploded perspective view of a display device according to some embodiments;

FIG. 3 is a plan view of a display panel according to some embodiments;

FIG. 4 is an enlarged plan view of a display panel according to some embodiments;

FIGS. 5A to 5C are cross-sectional views of a display panel according to some embodiments corresponding to the line I-I′ of FIG. 4;

FIG. 6A is a cross-sectional view of a display panel according to some embodiments corresponding to the line II-II′ of FIG. 4;

FIG. 6B is a cross-sectional view of a display panel according to a comparative example corresponding to the cross-section illustrated in FIG. 6A; and

FIG. 7 is an enlarged plan view of a display panel according to some embodiments.

### DETAILED DESCRIPTION

Since the inventive concept may have various changes and may have various forms, specific embodiments are illustrated in the drawings and described in detail in the text. However, this is not intended to limit the inventive concept to specific embodiments, and should be understood to include all modifications, equivalents and substitutes included in the spirit and scope of the inventive concept.

In this specification, when an element (or region, layer, part, etc.) is referred to as being “on”, “connected to”, or “coupled to” another element, it means that it may be directly placed on/connected to/coupled to other components, or a third component may be arranged between them.

Like reference numerals refer to like elements. Additionally, in the drawings, the thicknesses, proportions, and dimensions of components are exaggerated for effective description. “And/or” includes all of one or more combinations defined by related components.

It will be understood that the terms “first” and “second” are used herein to describe various components but these components should not be limited by these terms. The above terms are used only to distinguish one component from another. For example, a first component may be referred to as a second component and vice versa without departing from the scope of the inventive concept. The terms of a singular form may include plural forms unless otherwise specified.

In addition, terms such as “below”, “the lower side”, “on”, and “the upper side” are used to describe a relationship of components shown in the drawing. The terms are described as a relative concept based on a direction shown in the drawing.

In various embodiments of the inventive concept, the term “include,” “comprise,” “including,” or “comprising,” specifies a property, a region, a fixed number, a step, a process, an element and/or a component but does not exclude other properties, regions, fixed numbers, steps, processes, elements and/or components.

Unless otherwise defined, all terms (including technical and scientific terms) used herein have the same meaning as commonly understood by one of ordinary skill in the art to which this inventive concept belongs. In addition, terms such as terms defined in commonly used dictionaries should be interpreted as having a meaning consistent with the meaning in the context of the related technology, and it should not be construed in an overly ideal or overly formal sense unless explicitly defined here.

Hereinafter, a display panel according to some embodiments of the inventive concept will be described in more detail with reference to the drawings.

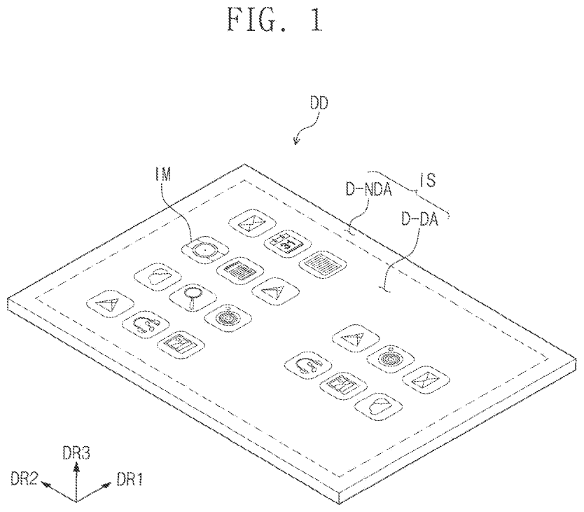

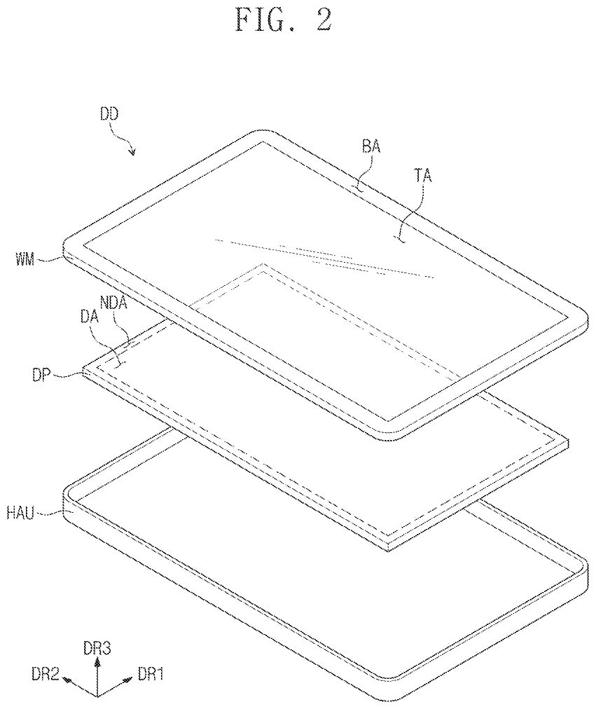

FIG. 1 is a perspective view of a display device according to some embodiments. FIG. 2 is an exploded perspective view of a display device according to some embodiments.

The display device DD may be a device that is activated according to an electrical signal and displays an image IM. The display device DD may include various embodiments that provide the image IM to a user. For example, the display device DD may be a large device such as a television or an external billboard, or a small or medium-sized device such as a monitor, a mobile phone, a tablet, a computer, a navigation system, or a game machine. However, the embodiments of the display device DD are not limited thereto unless departing from the concept of the inventive concept.

Referring to FIG. 1, the display device DD may have a rectangular shape having short sides extending in a first direction DR1 and long sides extending in a second direction DR2 on the plane. However, the inventive concept is not limited thereto, and the display device DD may have various shapes, such as a circular shape or a polygonal shape.

The display device DD may display the image IM in the third direction DR3 through a display surface IS parallel to the planes defined by the first and second directions DR1 and DR2. The third direction DR3 may be substantially parallel to the normal direction of the display surface IS. The display surface IS on which the image IM is displayed may correspond to a front surface of the display device DD. The image IM may include a still image as well as a dynamic image. FIG. 1 illustrates icon images as an example of the image IM.

According to some embodiments, the front (or upper) and rear (or lower) of each member (or unit) may be defined based on the direction in which the image IM is displayed. The front surface and the rear surface may be opposite to each other in the third direction DR3, and the respective normal directions of the front surface and the rear surface may be substantially parallel to the third direction DR3. A separation distance between the front surface and the rear surface in the third direction DR3 may correspond to the thickness of the member (or unit).

In the present specification, “on the plane” may be defined as a state viewed from the third direction DR3. In this specification, “on the cross-section” may be defined as a state viewed from the first direction DR1 or the second direction DR2. However, the directions indicated by the first to third directions DR1, DR2, and DR3 are relative concepts and may be converted to other directions.

FIG. 1 illustrates the display device DD having a planar display surface IS. However, the shape of the display surface IS of the display device DD is not limited thereto, and according to some embodiments, the display device DD may be a curved shape or a three-dimensional shape.

The display device DD may be flexible. “Flexible” refers to a property that may be bent, and may include everything from a completely foldable structure to a structure that may be bent to the level of several nanometers. For example, the flexible display device DD may be a curved device or a foldable device. The embodiments of the inventive concept are not limited thereto, and the display device DD may be a rigid one.

The display surface IS of the display device DD may include a display part D-DA and a non-display part D-NDA. The display part D-DA may be a part on which the image IM is displayed within the front surface of the display device DD, and the user may visually recognize the image IM through the display part D-DA. Although the present embodiments illustrate the display part D-DA having a rectangular shape on the plane, the display part D-DA may have various shapes depending on the design of the display device DD.

The non-display part D-NDA may be a part on which the image IM is not displayed within the front surface of the display device DD. The non-display part D-NDA may have a predetermined color and may be a part that blocks light. The non-display part D-NDA may be adjacent to the display part D-DA. For example, the non-display part D-NDA may be located outside the display part D-DA to surround the display part D-DA. However, this is illustrated by way of example, and the non-display part D-NDA may be adjacent to only one side of the display part D-DA or may be located on a side surface of the display device DD instead of the front surface. Also, the embodiments of the inventive concept are not limited thereto, and the non-display part D-NDA may be omitted.

The display device DD according to some embodiments may sense an external input applied from the outside. The external input may have various forms, such as externally provided pressure, temperature, light, and the like. The external input may include an input that is applied in proximity to the display device DD (e.g., hovering) as well as an input that makes contact with the display device DD (e.g., touching by a user's hand or a pen).

Referring to FIG. 2, the display device DD may include a window WM, a display panel DP, and an outer case HAU. The window WM and the outer case HAU may be combined to form an exterior of the display device DD, and may provide an internal space capable of accommodating components of the display device DD such as the display panel DP.

The window WM may be located on the display panel DP. The window WM may protect the display panel DP from external impact. A front surface of the window WM may correspond to the display surface IS of the display device DD described above. The front surface of the window WM may include a transmission area TA and a bezel area BA.

The transmission area TA of the window WM may be an optically transparent area. The window WM may transmit an image provided by the display panel DP through the transmission area TA, and the user may view the image. The transmission area TA may correspond to the display part D-DA (refer to FIG. 1) of the display device DD.

The window WM may include an optically transparent insulating material. For example, the window WM may include glass, sapphire, or plastic. The window WM may have a single-layered or multi-layered structure. The window WM may further include a functional layer such as an anti-fingerprint layer, a phase control layer, and a hard coating layer located on the optically transparent substrate.

The bezel area BA of the window WM may be an area provided by depositing, coating, or printing a material having a predetermined color on the optically transparent substrate. The bezel area BA of the window WM may prevent one configuration of the display panel DP overlapping the bezel area BA from being visually recognized to the outside. The bezel area BA may correspond to the non-display part D-NDA (refer to FIG. 1) of the display device DD.

The display panel DP may be located between the window WM and the outer case HAU. The display panel DP according to some embodiments may be a light emitting display panel, but is not particularly limited thereto. For example, the display panel DP may be an organic light emitting display panel, an inorganic light emitting display panel, or a quantum dot light emitting display panel. The light emitting layer of the organic light emitting display panel may include an organic light emitting material, and the light emitting layer of the inorganic light emitting display panel may include an inorganic light emitting material. The light emitting layer of the quantum dot light emitting display panel may include a quantum dot and a quantum rod. Hereinafter, the display panel DP is described as the organic light emitting display panel.

The display panel DP may include a display area DA that displays the image according to an electrical signal and a non-display area NDA adjacent to the display area DA. The display area DA may overlap the transmission area TA of the window WM. Meanwhile, in the present specification, “the region/part and the region/part overlap” is not limited to having the same area and/or the same shape. The image generated in the display area DA may be viewed from the outside through the transmission area TA.

The non-display area NDA may be adjacent to the display area DA. For example, the non-display area NDA may surround the display area DA. However, the inventive concept is not limited thereto, and the non-display area NDA may be defined in various shapes. The non-display area NDA may be an area in which a driving circuit or driving wiring for driving elements located in the display area DA, various signal lines providing electrical signals to the elements, and pads are located. The non-display area NDA may overlap the bezel area BA of the window WM, and instances of components of the display panel DP located in the non-display area NDA may be prevented from being visually recognized by the bezel area BA.

In addition, the display device DD according to some embodiments may further include an anti-reflection member located on the display panel DP. The anti-reflection member may prevent or reduce reflection of external light incident from the outside of the display device DD. The anti-reflection member may include a polarizing layer, a phaser, a destructive interference structure, or a plurality of color filters.

The display device DD according to some embodiments may further include an input sensor located on the display panel DP. The input sensor may acquire coordinate information of an external input applied from the outside of the display device DD. The input sensor included in the display device DD may be driven in various ways such as a capacitive method, a resistive method, an infrared method, or a pressure method, but the embodiments of the inventive concept are not limited thereto.

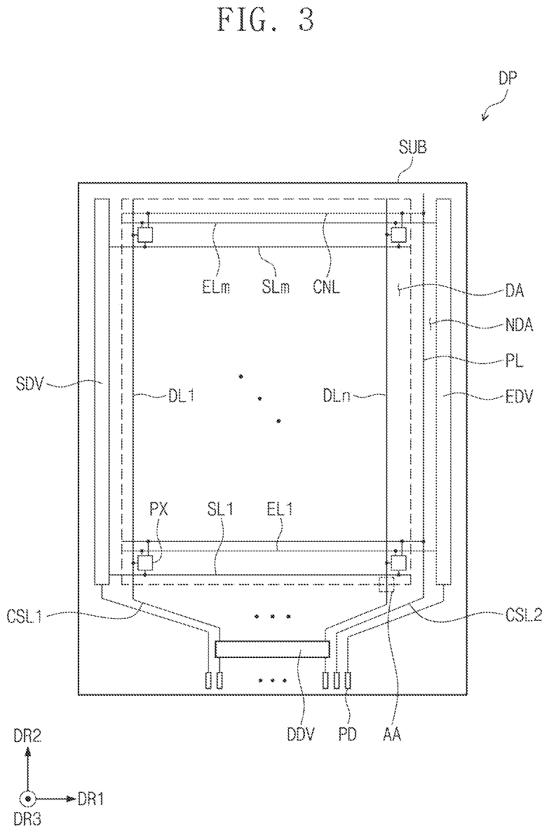

FIG. 3 is a plan view of a display panel according to some embodiments. FIG. 3 schematically illustrates one configuration of the display panel DP as viewed in the third direction DR3.

Referring to FIG. 3, the display panel DP may include a substrate SUB, a plurality of pixels PX, a plurality of signal lines SL1 to SLm, DL1 to DLn, EL1 to Elm, CSL1, CSL2, and PL electrically connected to the pixels PX, a scan driver SDV, a data driver DDV, and an emission driver EDV.

The substrate SUB may include the display area DA and non-display area NDA described above. The substrate SUB may provide a base surface on which electrical elements and signal lines of the display panel DP are located. FIG. 3 illustrates the substrate SUB having a rectangular shape parallel to each of the first and second directions DR1 and DR2 on the plane but the shape of the substrate SUB is not limited thereto, and various shapes may be designed according to the structure of the display device DD (refer to FIG. 1).

Each of the pixels PX may include a pixel driving circuit including a light emitting element, transistors (e.g., a switching transistor, a driving transistor, etc.) connected to the light emitting element, and at least one capacitor. Each of the pixels PX may be located in the display area DA to emit light according to an applied electrical signal. However, the embodiments of the inventive concept are not limited thereto, and some of the pixels PX may include transistors located in the non-display area NDA.

Each of the scan driver SDV, the data driver DDV, and the emission driver EDV may be located in the non-display area NDA. However, the embodiments of the inventive concept are not limited thereto, and according to some embodiments, at least one of the scan driver SDV, the data driver DDV, or the emission driver EDV may overlap the display area DA.

The data driver DDV is provided in the form of an integrated circuit chip defined as a driving chip, and may be mounted in the non-display area NDA of the display panel DP. However, the embodiments of the inventive concept are not limited thereto, and the data driver DDV may be mounted on a separate flexible circuit board electrically connected to the display panel DP.

The plurality of signal lines SL1 to SLm, DL1 to DLn, EL1 to ELm, CSL1, CSL2, and PL may include a plurality of scan lines SL1 to SLm, a plurality of data lines DL1 to DLn, a plurality of emission lines EL1 to ELm, first and second control lines CSL1 and CSL2, and a power line PL. Here, m and n are natural numbers.

The scan lines SL1 to SLm may extend in the first direction DR1 to be connected to the scan driver SDV. The data lines DL1 to DLn may extend in the second direction DR2 to be connected to the data driver DDV. The emission lines EL1 to ELm may extend in the first direction DR1 to be connected to the emission driver EDV.

The power line PL may extend in the second direction DR2 to be located on the non-display area NDA. According to some embodiments, the power line PL may be located between the display area DA and the emission driver EDV, but the arrangement position of the power line PL is not limited thereto. The power line PL may be electrically connected to the pixels PX through a connection line CNL connected to the power line PL. The power line PL may be located on a layer different from the connection line CNL and connected through a contact hole, or located on the same layer and formed integrally. The shape of the power line PL is not limited to any one embodiment as long as it is connected to the pixels PX to apply a predetermined voltage.

The first control line CSL1 may be connected to the scan driver SDV. The second control line CSL2 may be connected to the emission driver EDV.

The pads PD may be located adjacent to the lower end of the non-display area NDA. The pads PD may be located closer to the lower end of the display panel DP than the data driver DDV. The pads PD may be arranged in the first direction DR1. The display device DD (refer to FIG. 1) may further include a circuit board including a timing controller for controlling operations of the scan driver SDV, the data driver DDV, and the emission driver EDV and a voltage generator for generating a voltage, and the pads PD may be parts connected to the circuit board.

The pads PD may be respectively connected to corresponding signal lines among the plurality of signal lines SL1 to SLm, DL1 to DLn, EL1 to ELm, CSL1, CSL2, and PL. According to some embodiments, the data lines DL1 to DLn, the power line PL, and the first and second control lines CSL1 and CSL2 may be connected to the pads PD. The data lines DL1 to DLn may be connected to the data driver DDV, and the data driver DDV may be electrically connected to pads PD corresponding to of the respective data lines DL1 to DLn.

The scan driver SDV may generate scan signals in response to a scan control signal. The scan signals may be applied to the pixels PX through the scan lines SL1 to SLm. The data driver DDV may generate data voltages corresponding to the image signals in response to the data control signals. The data voltages may be applied to the pixels PX through the data lines DL1 to DLn. The emission driver EDV may generate emission signals in response to emission control signals. The emission signals may be applied to the pixels PX through the emission lines EL1 to ELm.

The pixels PX may be provided with the data voltages in response to the scan signals. Each of the pixels PX may display an image by emitting light having a luminance corresponding to the data voltages in response to the emission signals. The emission time of the pixels PX may be controlled by emission signals. Accordingly, the display panel DP may output the image through the display area DA by the pixels PX.

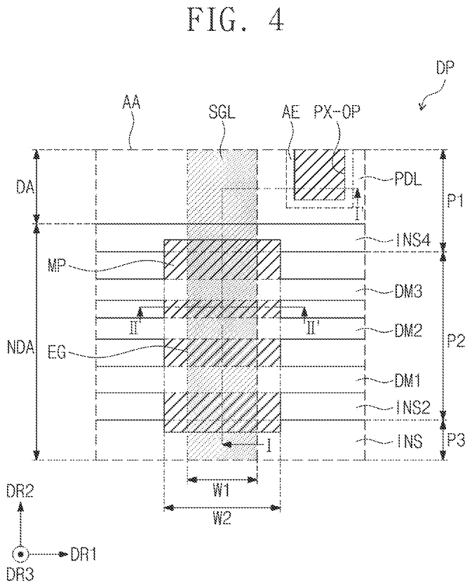

Meanwhile, one end of an organic insulating film of the display panel DP, which will be described later, may be adjacent to the boundary between the display area DA and the non-display area NDA, and the organic insulating film may be sealed by an inorganic layer that prevents or reduces the ingress of moisture. Accordingly, at least some of the plurality of signal lines SL1 to SLm, DL1 to DLn, EL1 to ELm, CSL1, CSL2, and PL may be exposed from the organic insulating film on the non-display area NDA. A conductive pattern of the inventive concept may cover a part of the signal line exposed from the organic insulating film to protect the signal line and improve the reliability of the signal line, and this will be described in detail with reference to FIG. 4 in which an area AA of FIG. 3 is enlarged and subsequent drawings.

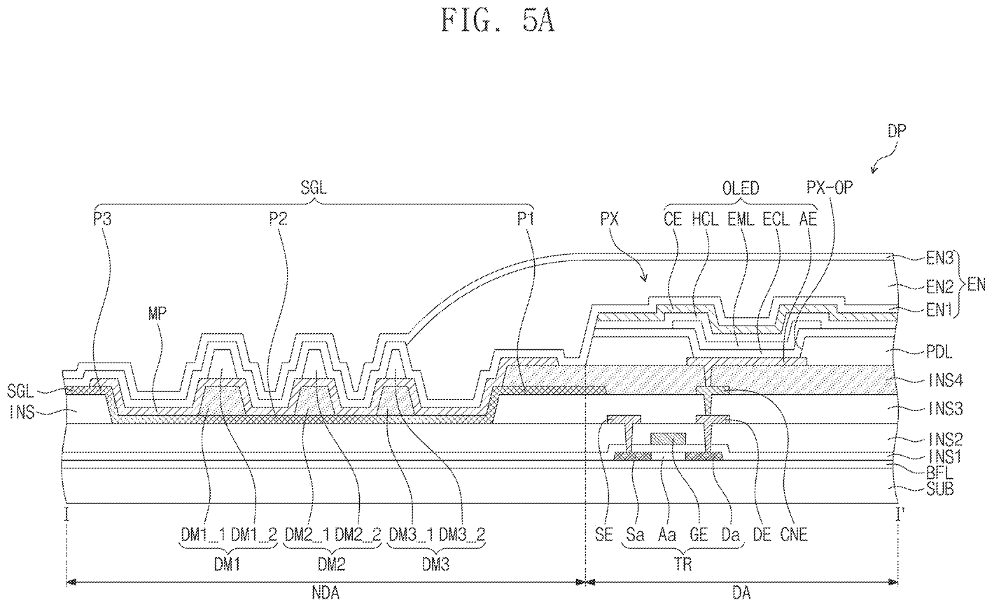

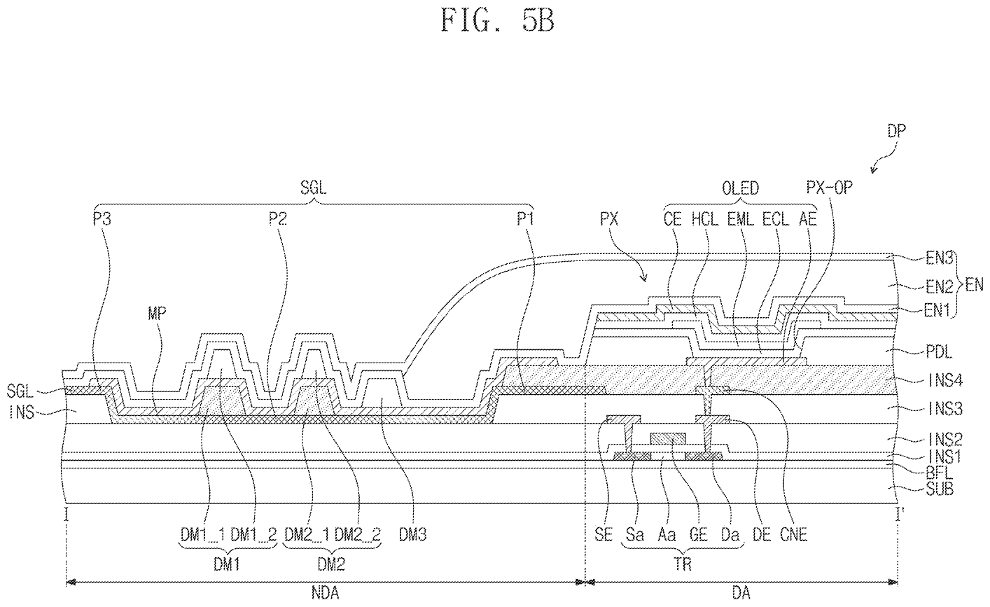

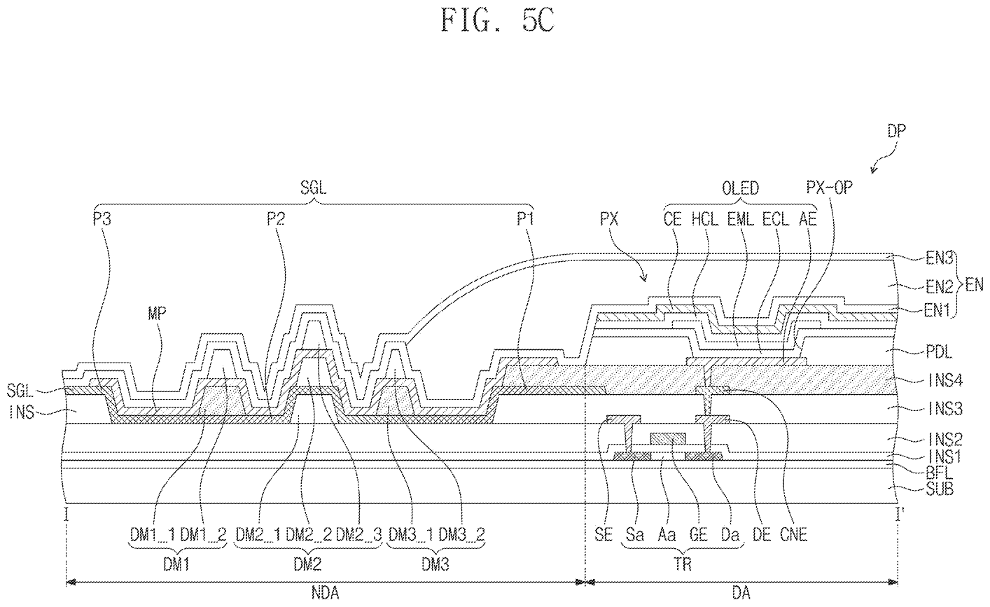

FIG. 4 is a plan view of a display panel according to some embodiments, which is an enlarged view of an area AA of FIG. 3. FIGS. 5A to 5C are cross-sectional views of a display panel according to some embodiments corresponding to the line I-I′ of FIG. 4. The display panels DP illustrated in FIGS. 5A to 5C have substantially the same configuration, but differ in some configurations.

Referring to FIGS. 4 and 5A, the signal line SGL may correspond to one of the plurality of signal lines SL1 to SLm, DL1 to DLn, EL1 to ELm, CSL1, CSL2, and PL of FIG. 3 described above. For example, the signal line SGL illustrated in FIG. 4 may correspond to one of the data lines DL1 to DLn (refer to FIG. 3) located in one area AA. However, the embodiments of the signal line SGL are not limited to any wiring that is connected to the pixels PX and transmits a signal.

A cross section of the display panel DP illustrated in FIG. 5A may correspond to one pixel PX and a portion of the signal line SGL. Referring to FIG. 5A, the display panel DP may include a substrate SUB, a pixel PX, an encapsulation layer EN, a plurality of insulating films INS1, INS2, INS3, and INS4, a signal line SGL, and a conductive pattern MP. The substrate SUB may include a display area DA and a non-display area NDA as described above.

The substrate SUB may include a glass substrate, a metal substrate, a polymer substrate, or an organic/inorganic composite substrate. According to some embodiments, the substrate SUB may include a synthetic resin layer. For example, the synthetic resin layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, a perylene-based resin, or a polyimide-based resin. However, the material of the substrate SUB is not limited to the above example.

A buffer layer BFL may be located on the substrate SUB. The buffer layer BFL may include at least one inorganic layer. For example, the buffer layer BFL may include at least one of a silicon oxide layer or a silicon nitride layer. According to some embodiments, the buffer layer BFL may include alternately stacked silicon oxide layers and silicon nitride layers. The buffer layer BFL may improve the bonding force between the substrate SUB and a semiconductor of a transistor TR, and may prevent or reduce instances of foreign substances being introduced into the transistor TR.

The pixel PX may be located on the display area DA of the substrate SUB. The pixel PX may include a light emitting element OLED and the transistor TR connected to the light emitting element OLED.

The pixel PX and the signal line SGL electrically connected to the pixel PX may be formed of at least one insulating layer, a conductive pattern part overlapping the insulating layer, and a semiconductor pattern. After forming an insulating layer, a semiconductor layer, and a conductive layer on the substrate SUB by coating, deposition, and the like, by patterning the insulating layer, the semiconductor layer, and the conductive layer by photolithography, the semiconductor pattern, the conductive pattern part, the signal line SGL, and the like of the display panel DP may be formed. The transistor TR may include a source region Sa, a drain region Da, a channel region Aa, and a gate electrode GE. The source region Sa, the drain region Da, and the channel region Aa of the transistor TR may be formed of the semiconductor pattern.

The semiconductor pattern of the transistor TR may be located on the buffer layer BFL. The semiconductor pattern of the transistor TR may include a silicon semiconductor, and may include a single crystal silicon semiconductor, a polysilicon semiconductor, or an amorphous silicon semiconductor. The embodiments of the inventive concept are not limited thereto, and the semiconductor pattern of the transistor TR may include an oxide semiconductor. The semiconductor pattern according to some embodiments of the inventive concept may be formed of various materials as long as it has semiconductor properties, and is not limited to any one embodiment.

The semiconductor pattern of the transistor TR may be divided into a plurality of regions according to conductivity. For example, the semiconductor pattern may have different electrical properties depending on whether it is doped or whether metal oxide is reduced. A region having high conductivity in the semiconductor pattern may serve as an electrode or a signal line, and may correspond to the source region Sa and the drain region Da of the transistor TR. The non-doped or non-reduced region having relatively low conductivity may correspond to the channel region Aa (or active region) of the transistor TR.

The plurality of insulating films INS1, INS2, INS3, and INS4 may be stacked on the substrate SUB. The plurality of insulating films INS1, INS2, INS3, and INS4 may include first to fourth insulating films INS1, INS2, INS3, and INS4 sequentially stacked on the substrate SUB.

The first to fourth insulating films INS1, INS2, INS3, and INS4 may include an inorganic film or an organic film. For example, the inorganic film may include at least one of aluminum oxide, titanium oxide, silicon oxide, silicon nitride, silicon oxynitride, zirconium oxide, or hafnium oxide. The organic film may include a phenol-based polymer, an acrylic polymer, an imide-based polymer, an arylether-based polymer, an amide-based polymer, a fluorine-based polymer, a p-xylene-based polymer, a vinyl alcohol-based polymer, and a polymer combining these polymers. However, the material of the plurality of insulating films INS1, INS2, INS3, and INS4 is not limited to the above example.

The first insulating film INS1 may be located on the buffer layer BFL to cover the semiconductor pattern of the transistor TR. According to some embodiments, the first insulating film INS1 may include an inorganic film having a single-layer or multi-layer structure.

The gate electrode GE of the transistor TR may be located on the first insulating film INS1. The gate electrode GE may overlap the channel region Aa of the transistor TR on the plane. According to some embodiments, the gate electrode GE may function as a mask in the process of doping the semiconductor pattern.

The second insulating film INS2 may be located on the first insulating film INS1 to cover the gate electrode GE. According to some embodiments, the second insulating film INS2 may include an inorganic film and/or an organic film. The inorganic film of the second insulating film INS2 may have a single-layer or multi-layer structure.

A source electrode SE and a drain electrode DE may be located on the second insulating film INS2. The source electrode SE may be connected to the source region Sa through a contact hole penetrating the first and second insulating films INS1 and INS2. The drain electrode DE may connect a contact hole passing through the first and second insulating films INS1 and INS2 to the drain region Da. The source electrode SE and the drain electrode DE may be arranged such that it is spaced apart from each other on the second insulating film INS2.

The third insulating film INS3 may be located on the second insulating film INS2 to cover the source electrode SE and the drain electrode DE. According to some embodiments, the third insulating film INS3 may include an organic film. The third insulating film INS3 including the organic film may provide a flat upper surface.

The connecting electrode CNE may be located on the third insulating film INS3. The connection electrode CNE may electrically connect the transistor TR and the light emitting element OLED. The connection electrode CNE may be connected to the drain electrode DE through a contact hole penetrating the third insulating film INS3.

The fourth insulating film INS4 may be located on the third insulating film INS3 to cover the connection electrode CNE. According to some embodiments, the fourth insulating film INS4 may include an organic film. The fourth insulating film INS4 including the organic film may provide a flat upper surface. Hereinafter, in this specification, the fourth insulating film INS4 including the organic film may be referred to as an organic insulating film INS4.

The light emitting element OLED may be located on the organic insulating film INS4. The light emitting element OLED may include a pixel electrode AE, a counter electrode CE, a hole control layer HCL, an electron control layer ECL, and a light emitting layer EML. The pixel electrode AE may be an anode electrode, and the counter electrode CE may be a cathode electrode.

For example, the light emitting element OLED may include an organic light emitting element, a quantum dot light emitting element, a micro LED light emitting element, or a nano LED light emitting element. However, the embodiments of the inventive concept are not limited thereto, and the light emitting element OLED may include various embodiments as long as light is generated or the amount of light may be controlled according to an electrical signal.

The pixel electrode AE may be located on the organic insulating film INS4. The pixel electrode AE may be connected to the connection electrode CNE through a contact hole penetrating the organic insulating film INS4. The pixel electrode AE may be electrically connected to the transistor TR through the connection electrode CNE.

A pixel defining film PDL may be located on the organic insulating film INS4. In the pixel defining film PDL, an emission opening part PX-OP exposing a portion of the pixel electrode AE may be defined. One area of the pixel electrode AE exposed by the emission opening part PX-OP may correspond to an emission area.

The pixel defining film PDL may be formed of a polymer resin. For example, the pixel defining film PDL may include a polyacrylate-based resin or a polyimide-based resin. The pixel defining film PDL may be formed by further including an inorganic material in addition to the polymer resin. In addition, the pixel defining film PDL may be formed of an inorganic material. For example, the pixel defining film PDL may be formed including silicon nitride (SiNx), silicon oxide (SiOx), silicon oxynitride (SiOxNy), or the like.

Meanwhile, according to some embodiments, the pixel defining film PDL may include a light absorbing material. The pixel defining film PDL may include a black coloring agent. The black coloring agent may include a black dye or a black pigment. The black coloring agent may include a metal such as carbon black or chromium, or an oxide thereof.

The hole control layer HCL may be located on the pixel electrode AE and the pixel defining film PDL. The hole control layer HCL may be commonly located on the pixels PX. The hole control layer HCL may include at least one of a hole transport layer or a hole injection layer.

The light emitting layer EML may be located on the hole control layer HCL. The light emitting layer EML may be located in an area corresponding to the emission opening part PX-OP. That is, the light emitting layers EML of the pixels PX may be formed in the form of light emitting patterns separated from each other. However, the embodiments of the inventive concept re not limited thereto.

A light emitting layer EML may provide a predetermined color light. For example, the light emitting layer EML may generate any one of red, green, and blue light. However, the embodiments of the inventive concept are not limited thereto, and the light emitting layer EML may generate white light by combining red, green, and blue light emitting materials.

The light emitting layer EML may include an organic light emitting material and/or an inorganic light emitting material. For example, the light emitting layer EML may include a fluorescent or phosphorescent material, a metal organic complex light emitting material, or quantum dots. According to some embodiments, the light emitting layer EM may have a multilayer structure. For example, the light emitting layer EML may include a primary light emitting layer and an auxiliary light emitting layer located on the primary light emitting layer. The primary light emitting layer and the auxiliary light emitting layer may be provided in different thicknesses according to the wavelength of the emitted light, and by arranging an auxiliary light emitting layer, the resonance distance of the light emitting element OLED may be adjusted. In addition, color purity of light output from the light emitting layer EML may be improved by arranging the auxiliary light emitting layer.

The electron control layer ECL may be located on the light emitting layer EML. The electron control layer ECL may be commonly arranged on the pixels PX. The electron control layer ECL may include at least one of an electron transport layer or an electron injection layer.

The counter electrode CE may be located on the electron control layer ECL. The counter electrode CE may be commonly located in the pixels PX. A common voltage may be provided to the pixels PX through the counter electrode CE.

Each of the pixel electrode AE and the counter electrode CE may be a transmissive electrode, a transflective electrode, or a reflective electrode. The transmissive electrode may include a transparent metal oxide, for example, indium tin oxide (ITO), indium zinc oxide (IZO), zinc oxide (ZnO), or indium tin zinc oxide (ITZO). The transflective electrode or reflective electrode may include Ag, Mg, Cu, Al, Pt, Pd, Au, Ni, Nd, Ir, Cr, Li, Ca, LiF/Ca (laminated structure of LiF and Ca), LiF/Al (laminated structure of LiF and Al), Mo, Ti, Yb, W, or a compound or mixture including them (e.g., AgMg, AgYb, or MgYb).

The pixel electrode AE and the counter electrode CE may have a multi-layer structure including a reflective or semi-transmissive film formed of the above material, and a transparent conductive film formed of indium tin oxide (ITO), indium zinc oxide (IZO), zinc oxide (ZnO), and indium tin zinc oxide (ITZO). For example, the electrode having a plurality of layer structures may have a three-layer structure of ITO/Ag/ITO, but is not limited thereto.

A first voltage may be applied to the pixel electrode AE, and a common voltage may be applied to the counter electrode CE through a signal line providing a common voltage. Holes and electrons injected into the light emitting layer EML combine to form an exciton, and as the exciton transitions to a ground state, the light emitting element OLED may emit light within the display area DA.

The encapsulation layer EN may be located on the light emitting element OLED to encapsulate the light emitting element OLED. The encapsulation layer EN may include at least one insulating layer. According to some embodiments, the encapsulation layer EN may include a plurality of inorganic layers EN1 and EN3 and at least one organic layer EN2 located between the inorganic layers EN1 and EN3. The first inorganic layer EN1 may be located on the counter electrode CE. The organic layer EN2 and the second inorganic layer EN3 may be sequentially arranged on the first inorganic layer EN1. The organic layer EN2 may provide a flat upper surface to a structure located on the organic layer EN2. However, the stacked structure of the encapsulation layer EN is not limited to the illustrated embodiments.

The first and second inorganic layers EN1 and EN3 may protect the light emitting element OLED from moisture and/or oxygen. In addition, the first and second inorganic layers EN1 and EN3 may be located in the display area DA and may cover an insulating film including an organic material to prevent or reduce instances of moisture penetrating from the outside. The first and second inorganic layers EN1 and EN3 may include at least one of aluminum oxide, titanium oxide, silicon oxide, silicon nitride, silicon oxynitride, zirconium oxide, or hafnium oxide, but the material is not limited to the above examples.

The organic layer EN2 may protect the light emitting element OLED from foreign substances such as dust particles. For example, the organic layer EN2 may include an acrylic resin, but the material is not limited thereto.

Referring to FIGS. 4 and 5A, the first insulating film INS1 and the second insulating film INS2 including the inorganic film may extend from the display area DA toward the non-display area NDA. The third insulating film INS3 and the fourth insulating film INS4 (the organic insulating film INS4) including the organic film may extend from the display area DA toward the non-display area NDA, and the ends of the third insulating film INS3 and the fourth insulating film INS4 may be adjacent to the boundary between the display area DA and the non-display area NDA. That is, each of the first insulating film INS1 and the second insulating film INS2 may extend longer toward the end of the display panel DP on the non-display area NDA than the third insulating film INS3 and the fourth insulating film INS4, respectively. Therefore, in the non-display area NDA in which the signal line SGL is located, there may be an area in which the third insulating film INS3 and the fourth insulating film INS4 including the organic film (the organic insulating film INS4) are not located.

The signal line SGL extends from the display area DA and may be located on the non-display area NDA. The signal line SGL may be electrically connected to the pixel PX through a connection line or an electrode in the display area DA. The signal line SGL may be connected to a pad PD (refer to FIG. 3) or a driver within the non-display area NDA.

The signal line SGL may include a first part P1, a second part P2, and a third part P3 extending in the second direction DR2. The first part P1 may be a part overlapping the organic insulating film INS4. The first part P1 may be located on the third insulating film INS3 and covered by the organic insulating film INS4. The first part P1 may overlap the display area DA and may extend from the display area DA toward the non-display area NDA. The first part P1 may cover the inclined surface of the third insulating film INS3 corresponding to one end of the third insulating film INS3.

The second part P2 may extend from the first part P1 and may be spaced apart from the organic insulating film INS4. That is, the second part P2 may not overlap the organic insulating film INS4 and may be exposed from the organic insulating film INS4. The display panel DP includes an area where the organic insulating film INS4 is not located within the non-display area NDA, and as one end of the organic insulating film INS4 is covered by the inorganic layers EN1 and EN3, it is possible to prevent or reduce instances of external moisture permeating into the display area DA through the organic insulating film INS4.

Meanwhile, the display panel DP may further include an insulating film INS located in an area adjacent to the end of the display panel DP, and the insulating film INS may include an organic material. The third part P3 of the signal line SGL extends from the second part P2 and may overlap the insulating film INS. However, in the display panel DP according to some embodiments, the insulating film INS may be omitted.

The signal line SGL may include a conductive material. The signal line SGL may include a metal material. According to some embodiments, the signal line SGL may have a multilayer structure including a plurality of conductive layers sequentially stacked. The metal material included in the signal line SGL may be a material having a relatively low electrical resistance. Accordingly, the signal line SGL may smoothly transmit an electrical signal, and heat generation may be prevented or reduced.

The signal line SGL may include the same material as the connection electrode CNE located on the third insulating film INS3. The signal line SGL may be simultaneously formed in the process of forming the connection electrode CNE. At least portion of the signal line SGL may be located on the same layer as the connection electrode CNE.

The conductive pattern MP is located on the non-display area NDA and may overlap the second part P2 of the signal line SGL. The conductive pattern MP may be arranged to be spaced apart from the pixel electrode AE on the plane. The conductive pattern MP may protect the second part P2 of the signal line SGL exposed by the organic insulating film INS4.

The entire area of the second part P2 of the signal line SGL may overlap the conductive pattern MP. The second part P2 of the signal line SGL extends in the second direction DR2 and may include an edge EG exposed from the organic insulating film INS4, and the conductive pattern MP may cover the edge EG of the second part P2. At least a portion of the edge EG of the second part P2 may contact the conductive pattern MP.

The signal line SGL may have a first width W1 in the first direction DR1 intersecting the extension direction of the signal line SGL (e.g., the second direction DR2). The conductive pattern MP may have a second width W2 in the first direction DR1. The second width W2 of the conductive pattern MP may be greater than the first width W1 of the signal line SGL. Accordingly, the conductive pattern MP may sufficiently cover the edge EG of the second part P2 of the signal line SGL, and may prevent or reduce instances of foreign substances entering the second part P2 exposed from the organic insulating film INS4 and protect the signal line SGL. Accordingly, a failure of the signal line SGL may be prevented or reduced and the lifespan of the signal line SGL may be improved.

The conductive pattern MP may include a metal material. The conductive pattern MP may include a material different from the material included in the signal line SGL. The conductive pattern MP may include the same material as the pixel electrode AE of the light emitting element OLED. According to some embodiments, the conductive pattern MP may have the same stacked structure as the pixel electrode AE. For example, when the pixel electrode AE has a three-layer structure of ITO/Ag/ITO, the conductive pattern MP may also have the same three-layer structure of ITO/Ag/ITO.

The conductive pattern MP may be simultaneously formed in the same process step as that of the pixel electrode AE. For example, after depositing a conductive layer on the organic insulating film INS4 and the signal line SGL, the conductive layer is patterned to correspond to the regions where the pixel electrode AE and the conductive pattern MP are to be formed so that the pixel electrode AE and the conductive pattern MP may be simultaneously formed.

In the case of the comparative example in which the conductive pattern MP of the inventive concept is not located, in the etching process for forming a pixel electrode AE, a second part P2 of a signal line SGL exposed by an organic insulating film INS4 may be exposed to the etching solution. Accordingly, an edge EG of the second part P2 of the signal line SGL may be etched together. In this process, the edge EG of the second part P2 may have an undercut shape due to a difference in etching rates of materials constituting the signal line SGL. However, when the conductive pattern MP is designed to be formed on the second part P2 of the signal line SGL, in the etching process for forming the pixel electrode AE, the conductive layer deposited on the second part P2 may not be etched, and as the corresponding portion is formed of the conductive pattern MP, it is possible to protect the second part P2 of the signal line SGL at the same time.

By forming the conductive pattern MP simultaneously with the pixel electrode AE, the signal line SGL exposed by the organic insulating film INS4 may be protected without adding a process step. If a separate inorganic layer is stacked to protect the signal line SGL exposed by the organic insulating film INS4, an additional mask may be required. However, since the display panel DP of the inventive concept includes the conductive pattern MP, a configuration for protecting the signal line SGL may be formed through a simplified process without adding a mask.

The display panel DP may further include at least one dam located on the non-display area NDA. FIGS. 4 and 5A show embodiments in which a plurality of dams are provided, but embodiments of the inventive concept are not limited thereto, and the display panel DP may include one dam located on the non-display area NDA. In addition, the display panel DP according to some embodiments may include fewer or more dams than the dams DM1, DM2, and DM3 illustrated in FIGS. 4 and 5A.

Referring to FIGS. 4 and 5A, the plurality of dams DM1, DM2, and DM3 may include first to third dams DM1, DM2, and DM3 spaced apart from each other in the second direction DR2 on the non-display area NDA. Among the first to third dams DM1, DM2, and DM3, the first dam DM1 may be arranged to be farthest from the display area DA, and the third dam DM3 may be arranged closest to the display area DA.

The first to third dams DM1, DM2, and DM3 may be located on the second part P2. Each of the first to third dams DM1, DM2, and DM3 may extend in the first direction DR1 intersecting the extending direction of the second part P2.

At least one of the first to third dams DM1, DM2, or DM3 may be spaced apart from the organic layer EN2 of the encapsulation layer EN. The first to third dams DM1, DM2, and DM3 may control the flow of the organic layer EN2 of the encapsulation layer EN. When manufacturing the display panel DP, the organic material having fluidity may be cured to form the organic layer EN2 of the encapsulation layer EN, and the first to third dams DM1, DM2, and DM3 may prevent or reduce instances of the organic layer EN2 overflowing toward the outside of the non-display area NDA. As the flow of the organic layer EN2 is controlled by the first to third dams DM1, DM2, and DM3, a portion of the second part P2 may not overlap the organic layer EN2.

FIG. 5A illustrates the organic layer EN2 whose flow is controlled by the third dam DM3. Accordingly, the inclined surface corresponding to the end of the organic layer EN2 may face the third dam DM3. However, the embodiments of the inventive concept are not limited thereto, and the organic layer EN2 may cover the third dam DM3, and the flow of the organic layer EN2 may be blocked by the second dam DM2.

The first to third dams DM1, DM2, and DM3 may be covered by the first and second inorganic layers EN1 and EN3 of the encapsulation layer EN. The first inorganic layer EN1 may contact upper surfaces of the first to third dams DM1, DM2, and DM3. The second inorganic layer EN3 may contact the first inorganic layer EN1 located on the first to third dams DM1, DM2, and DM3. The first and second inorganic layers EN1 and EN3 contact each other on the non-display area NDA to seal the organic layer EN2 located between the first and second inorganic layers EN1 and EN3 in the display area DA. Accordingly, it is possible to prevent or reduce instances of moisture flowing into the organic layer EN2 from the outside.

The first to third dams DM1, DM2, and DM3 may include a plurality of sub-dams. Referring to FIG. 5A, according to some embodiments, each of the first to third dams DM1, DM2, and DM3 includes first sub-dams DM1_1, DM2_1, DM3_1 and second sub-dams DM1_2, DM2_2, and DM3_2. The first sub-dams DM1_1, DM2_1, and DM3_1 may be located on the second sub-dams DM1_2, DM2_2, and DM3_2, respectively.

The first sub-dams DM1_1, DM2_1, and DM3_1 and the second sub-dams DM1_2, DM2_2, and DM3_2 may include an insulating material. The first sub-dams DM1_1, DM2_1, and DM3_1 may include the same material as the organic insulating film INS4. The first sub-dams DM1_1, DM2_1, and DM3_1 may be simultaneously formed in the organic insulating film INS4 forming process. However, the embodiments of the inventive concept are not necessarily limited thereto, and the first sub-dams DM1_1, DM2_1, and DM3_1 may include a material different from that of the organic insulating film INS4.

The second sub-dams DM1_2, DM2_2, and DM3_2 may include the same material as the pixel defining film PDL. The second sub-dams DM1_2, DM2_2, and DM3_2 may be simultaneously formed in the pixel defining film PDL forming process. However, the embodiments of the inventive concept are not necessarily limited thereto, and the second sub-dams DM1_2, DM2_2, and DM3_2 may include a material different from that of the pixel defining film PDL.

As the first sub-dams DM1_1, DM2_1, and DM3_1 are formed through the same process as the organic insulating film INS4, the conductive pattern MP may be located on the first sub-dams DM1_1, DM2_1, and DM3_1. The conductive pattern MP may extend toward the boundary of the second part P2 of the signal line SGL through between the first sub-dams DM1_1, DM2_1, and DM3_1 and the second sub-dams DM1_2, DM2_2, and DM3_2. One portion of the conductive pattern MP may contact the upper surfaces of the first sub-dams DM1_1, DM2_1, and DM3_1, and the other portion may contact the upper surface of the second part P2 of the signal line SGL.

The first to third dams DM1, DM2, and DM3 may have substantially the same height. However, the inventive concept is not limited thereto, and at least some of the first to third dams DM1, DM2, and DM3 may be designed to have different heights.

However, the configuration of the first to third dams DM1, DM2, and DM3 is not limited to that illustrated in FIG. 5A and may be modified. FIGS. 5B and 5C show first to third dams DM1, DM2, and DM3 having a configuration different from that of the embodiments of FIG. 5A. The configuration of the first to third dams DM1, DM2, and DM3 is not limited to any configuration as long as the flow of the organic layer EN2 may be controlled.

Referring to FIGS. 5B and 5C, at least one of the first to third dams DM1, DM2, or DM3 may have a different structure from the other dams. At least one of the first to third dams DM1, DM2, or DM3 may have a different height from the other dams.

Referring to FIG. 5B, the third dam DM3 may be configured as a single dam located on the conductive pattern MP. The third dam DM3 may be formed through the same process as the second sub-dams DM1_2 and DM2_2 of the first dam DM1 and the second dam DM2. The embodiments of the inventive concept are not limited to that shown in FIG. 5B, and all of the first to third dams DM1, DM2, and DM3 may be located on the conductive pattern MP, and in this case, the conductive pattern MP may contact the second part P2 without passing between sub-dams of the first to third dams DM1, DM2, and DM3.

Referring to FIG. 5C, the second dam DM2 may include a larger number of sub-dams than each of the first dam DM1 and the third dam DM3. The second dam DM1 may include sequentially stacked first to third sub-dams DM2_1, DM2_2, and DM2_3. The first sub-dam DM2_1 of the second dam DM2 may be located below the signal line SGL. The second part P2 of the signal line SGL may extend through between the first sub-dam DM2_1 and the second sub-dam DM2_2 of the second dam DM2. Accordingly, a portion of the second part P2 of the signal line SGL may contact the upper surface of the first sub-dam DM2_1 of the second dam DM2.

The second sub-dam DM2_2 of the second dam DM2 may be formed through the same process as the first sub-dams DM1_1 and DM3_1 of the first dam DM1 and the third dam DM3. The third sub-dam DM2_3 of the second dam DM2 may be formed through the same process as the second sub-dams DM1_2 and DM3_2 of the first dam DM1 and the third dam DM3. However, the embodiments of the inventive concept are not limited thereto, and the first dam DM1 or the third dam DM3 may have the structure of the second dam DM2 shown in FIG. 5C.

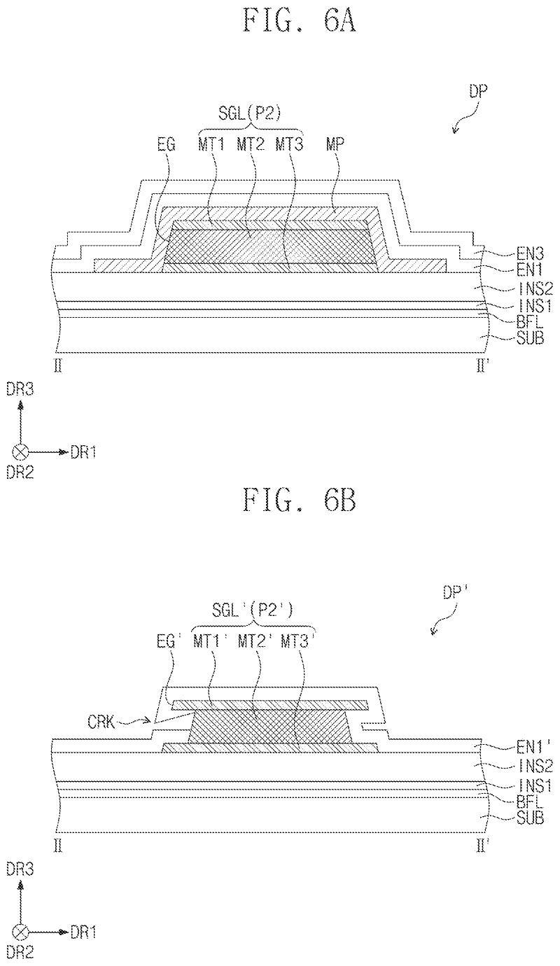

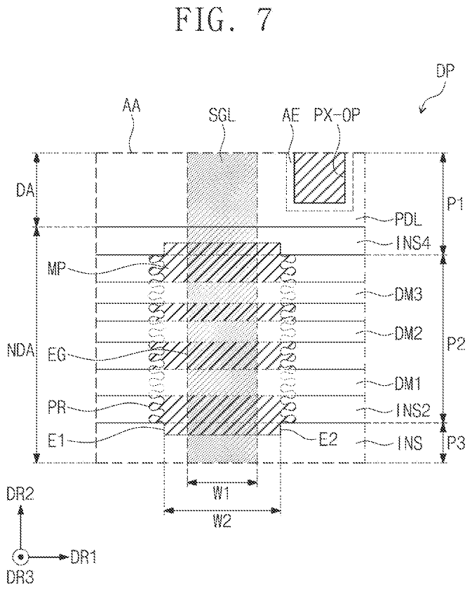

FIG. 6A is a cross-sectional view of a display panel according to some embodiments corresponding to the line II-II′ of FIG. 4. FIG. 6B is a cross-sectional view of a display panel according to a comparative example corresponding to the cross-section illustrated in FIG. 6A.

Referring to FIG. 6A, the signal line SGL may include first to third conductive layers MT1, MT2, and MT3 sequentially stacked. The third conductive layer MT3 may be located on the second insulating film INS2, the first conductive layer MT1 may be located on the third conductive layer MT3, and the second conductive layer MT2 may be located between the first conductive layer MT1 and the third conductive layer MT3.

Each of the first conductive layer MT1 and the third conductive layer MT3 may include a metal material having corrosion resistance. The first conductive layer MT1 and the third conductive layer MT3 may be located below and above the second conductive layer MT2, respectively, to protect the second conductive layer MT2 from scratches generated during a process. In addition, the first conductive layer MT1 and the third conductive layer MT3 may prevent or reduce corrosion of the second conductive layer MT2 due to moisture permeation. For example, each of the first conductive layer MT1 and the third conductive layer MT3 may include at least one of molybdenum, titanium, or an alloy thereof. According to some embodiments, the first conductive layer MT1 and the third conductive layer MT3 may include the same material. However, the material of the first conductive layer MT1 and the third conductive layer MT3 is not limited to the above example.

The second conductive layer MT2 may include a metal material having low resistivity. The second conductive layer MT2 may include a different material from each of the first conductive layer MT1 and the third conductive layer MT3. For example, the second conductive layer MT2 may include at least one of gold, silver, copper, aluminum, platinum, or an alloy thereof. However, the material of the second conductive layer MT2 is not limited to the above example.

The second conductive layer MT2 may have a thickness greater than each of the first conductive layer MT1 and the third conductive layer MT3. Since the second conductive layer MT2 including a material having a relatively low resistance has a large thickness, the signal line SGL may have a small resistance.

Side surfaces of the plurality of conductive layers MT1, MT2, and MT3 corresponding to the second part P2 may be defined as the edge EG of the second part P2. The edge EG of the second part P2 may be covered by the conductive pattern MP. The conductive pattern MP may cover the edge EG of the second part P2, and the conductive pattern MP may protect the signal line SGL by preventing or reducing instances of foreign substances being introduced through the edge EG of the second part P2.

As the conductive pattern MP is simultaneously formed through the same process as the pixel electrode AE (refer to FIG. 4), in the etching process for forming the pixel electrode AE, the edge EG of the second part P2 may not be exposed to the etching solution. Accordingly, it may be possible to prevent or reduce instances of an undercut shape being formed on the edge EG of the second part P2 due to a difference in etch rates between the plurality of conductive layers MT1, MT2, and MT3 including different materials.

The display panel DP′ of the comparative example illustrated in FIG. 6B may not include the conductive pattern MP of the inventive concept. A plurality of conductive layers MT1′, MT2′, and MT3′ of a signal line SGL′ on which the conductive pattern MP is not located may be exposed to an etching solution in an etching process for forming a pixel electrode. Accordingly, the plurality of conductive layers MT1′, MT2′, and MT3′ including different materials may be etched at different etch rates. For example, the second conductive layer MT2′ of the signal line SGL′ of the comparative embodiment may be etched relatively faster than the first conductive layer MT1′ and the third conductive layer MT3′. Accordingly, side surfaces of the first conductive layer MT1′ and the third conductive layer MT3′ may relatively protrude in the first direction DR1 than the side surfaces of the second conductive layer MT2′. Accordingly, the edge EG' corresponding to the second part P2′ of the signal line SGL′ of the comparative embodiment may have an undercut shape.

Referring to FIG. 6A, a first inorganic layer EN1 may be located on the conductive pattern MP. As the first inorganic layer EN1 is deposited on the upper surface of the conductive pattern MP having substantially no step difference, damage to the first inorganic layer EN1 may be prevented or reduced.

Referring to FIG. 6B, as the conductive pattern MP is not located, a first inorganic layer EN1′ may be directly located on the second part P2′ of the signal line SGL′ of the comparative embodiment. That is, in the comparative embodiment, the first inorganic layer EN1′ may contact the edge EG′ of the second part P2′. In the comparative embodiment, the first inorganic layer EN1′ may be formed to be curved by the edge EG′ of the second part P2′ having an undercut shape, and accordingly, a crack CRK in which a portion of the first inorganic layer EN1′ is broken may occur. Moisture may be introduced into the signal line SGL' from the outside due to the crack CRK of the first inorganic layer EN1′, and this may cause a defect in the signal line SGL′ or shorten the lifespan of the signal line SGL′.

However, since the display panel DP according to some embodiments of the inventive concept includes the conductive pattern MP covering a portion of the signal line SGL exposed from the organic insulating film INS4, it is possible to protect the signal line SGL and, at the same time, prevent or reduce damage to the inorganic layers EN1 and EN3 formed on the signal line SGL. Accordingly, reliability of the signal line SGL and the display panel DP may be improved.

FIG. 7 is a plan view of a display panel corresponding to an area AA of FIG. 3 according to some embodiments. FIG. 7 includes substantially the same configuration as the display panel DP illustrated in FIG. 4, and the above description may be applied in the same way. The conductive pattern MP of FIG. 7 has a different shape from the conductive pattern MP of FIG. 4 and will be mainly described.

Referring to FIG. 7, the conductive pattern MP includes one end E1 extending in the second direction DR2 and the other end E2 opposite to the one end E1 in the first direction DR1. Each of the one end E1 and the other end E2 of the conductive pattern MP may include a plurality of protruding parts PR.

The plurality of protruding parts PR may be arranged in the second direction DR2. The plurality of protruding parts PR may protrude in a direction parallel to the first direction DR1. The protruding parts PR included in the one end E1 and the protruding parts PR included in the other end E2 may protrude in opposite directions.

The plurality of protruding parts PR may include a curved surface. The plurality of protruding parts PR may have a substantially zipper shape. As the one end E1 of the conductive pattern MP includes the plurality of protruding parts PR, an extension length of the one end E1 may be relatively longer than that of the conductive pattern MP having one straight end shown in FIG. 4. Accordingly, a movement path of moisture flowing in through the one end E1 of the conductive pattern MP may be lengthened, and moisture permeation through the signal line SGL may be effectively prevented or reduced. Through this, the lifespan of the signal line SGL may be improved. However, as long as the extension length of the one end E1 of the conductive pattern MP may be increased, the shapes of the plurality of protruding parts PR are not limited to the illustrated ones. The description of the one end E1 of the conductive pattern MP described above may be equally applied to the other end E2.

As the conductive pattern according to some embodiments of the inventive concept covers a portion of the signal line exposed by the organic insulating film, it is possible to prevent or reduce instances of moisture or foreign substances from entering the signal line from the outside, and to protect the signal line from being damaged. The conductive pattern may be formed to be spaced apart from the pixel electrode through the same process as the pixel electrode included in the display panel, and accordingly, it is possible to protect the signal line without further arranging an additional inorganic layer for protecting the signal line. Accordingly, the display panel including the signal line having improved reliability may be manufactured through a simplified process.

As the conductive pattern according to some embodiments of the inventive concept is formed through the same process as the pixel electrode included in the display panel, the conductive pattern may prevent or reduce instances of a portion of the signal line from being etched to have an undercut shape in an etching process for forming the pixel electrode. Accordingly, it may be possible to prevent or reduce instances of cracks occurring in the inorganic layer deposited on the signal line by the signal line having the undercut shape. By preventing or reducing instances of cracks occurring in the inorganic layer, it may be possible to effectively block moisture flowing into the signal line.

Although aspects of some embodiments of the inventive concept have been described, it is understood that the inventive concept should not be limited to these embodiments but various changes and modifications may be made by one ordinary skilled in the art within the spirit and scope of the inventive concept according to the appended claims, and their equivalents.

What is claimed is:

1. A display panel comprising:
a signal line extending in a first direction;
an organic insulating film overlapping a first part of the signal line and not overlapping a second part of the signal line;
a pixel electrically connected to the signal line and including a transistor and a light emitting element including a pixel electrode on the organic insulating film; and
a conductive pattern covering at least a portion of an edge of the second part of the signal line.

2. The display panel of claim 1, wherein a width of the conductive pattern in a second direction intersecting the first direction is greater than a width of the second part in the second direction.

3. The display panel of claim 1, wherein one end of the conductive pattern comprises a plurality of protruding parts arranged along the first direction.

4. The display panel of claim 1, wherein the conductive pattern comprises a material different from that of the signal line.

5. The display panel of claim 1, wherein the conductive pattern comprises a same material as the pixel electrode.

6. The display panel of claim 1, wherein the signal line comprises a plurality of conductive layers that are sequentially stacked,
wherein the conductive pattern covers each side surface of the plurality of conductive layers.

7. The display panel of claim 1, further comprising at least one dam extending in the second direction intersecting the first direction and overlapping the second part of the signal line,
wherein the at least one dam is spaced apart from the organic insulating film.

8. The display panel of claim 7, wherein the at least one dam comprises:
a first sub-dam on the second part of the signal line; and
a second sub-dam on the first sub-dam,
wherein at least one of the first sub-dam or the second sub-dam comprises a same material as the organic insulating film.

9. The display panel of claim 8, wherein a portion of the conductive pattern is between the first sub-dam and the second sub-dam.

10. The display panel of claim 7, wherein the at least one dam is on the conductive pattern.

11. The display panel of claim 7, wherein the dam is provided in plurality, and the plurality of dams are spaced apart from each other in the first direction.

12. The display panel of claim 11, further comprising an encapsulation layer on the light emitting element, and including a plurality of inorganic layers and at least one organic layer between the plurality of inorganic layers,
wherein at least one of the plurality of dams is spaced apart from the organic layer.

13. The display panel of claim 12, wherein the plurality of inorganic layers cover the conductive pattern.

14. The display panel of claim 1, wherein the signal line comprises a data line providing a data voltage to the pixel and a power line configured to provide a power supply voltage to the pixel.

15. A display panel comprising:
a substrate including a display area and a non-display area;
a pixel on the display area and including a light emitting element;
a signal line electrically connected to the pixel and extending in one direction from the display area to the non-display area;
an organic insulating film on the signal line and exposing a portion of the signal line;
a conductive pattern on the non-display area and covering the portion of the signal line; and
at least one dam overlapping the conductive pattern and crossing the signal line.

16. The display panel of claim 15, wherein the light emitting element comprises:
a pixel electrode on the organic insulating film;
a counter electrode on the pixel electrode; and
a light emitting layer between the pixel electrode and the counter electrode,
wherein the conductive pattern is spaced apart from the pixel electrode.

17. The display panel of claim 16, wherein the conductive pattern comprises a same material as the pixel electrode.

18. The display panel of claim 15, wherein the signal line comprises a material different from that of the conductive pattern.

19. The display panel of claim 15, wherein an edge of the portion of the signal line is in contact with the conductive pattern.

20. The display panel of claim 15, wherein the signal line comprises:
data lines extending in a first direction, arranged along a second direction intersecting the first direction, and applying a data voltage to the pixel; and
at least one power line extending in the first direction and applying a power supply voltage to the pixel.
